(19) United States
(12) Patent Application Publication
(10) Pub. No.: US 2024/0023324 A1
(43) Pub. Date: Jan. 18, 2024

(54) THREE-DIMENSIONAL SEMICONDUCTOR STRUCTURE AND METHOD FOR FORMING SAME

(71) Applicant: CHANGXIN MEMORY TECHNOLOGIES, INC., Hefei City (CN)

(72) Inventor: Chao LIN, Hefei (CN)

(21) Appl. No.: 18/446,506

(22) Filed: Aug. 9, 2023

Related U.S. Application Data
(63) Continuation of application No. PCT/CN2023/088367, filed on Apr. 14, 2023.

(30) Foreign Application Priority Data
Jul. 18, 2022 (CN) 202210841856.6

(51) Int. Cl. H10B 12/00; H01L 23/522; H01L 23/528

(52) U.S. Cl. CPC H10B 12/488; H10B 12/05; H10B 12/482; H01L 23/5226; H01L 23/5283

(57) ABSTRACT

A three-dimensional semiconductor structure and a method for forming the same are provided. The method includes the following operations. A stack structure in a source region and a drain region is etched to form a plurality of parallel first trenches extending in the first direction in the stack structure in the source region and the drain region, in which a plurality of semiconductor layers retained in the channel region serve as a plurality of channel body layers. The channel body layers extend in a second direction, and each includes a plurality of channel areas arranged in the second direction. A through via is formed in an end of the channel body layers in the second direction and penetrates the end. A conductive material is filled in the through via to form a grounded conductive plug.

### CROSS-REFERENCE TO RELATED APPLICATIONS

This application is a U.S. continuation application of International Application No. PCT/CN2023/088367, filed Apr. 14, 2023, which claims priority to Chinese Patent Application No. 202210841856.6, filed Jul. 18, 2022. International Application No. PCT/CN2023/088367 and Chinese Patent Application No. 202210841856.6 are incorporated herein by reference in their entireties.

### BACKGROUND

Dynamic random access memory (DRAM) is a semiconductor memory device commonly used in computers, which is composed of a plurality of repeated memory cells. Each of the memory cells usually includes a capacitor and a transistor. The gate of the transistor is connected with a word line, the drain of the transistor is connected with a bit line, and the source of the transistor is connected with the capacitor. A voltage signal on the word line can control on and off of the transistor, so that data information stored in the capacitor is read or data information is written into the capacitor through the bit line for storage.

In order to improve integration, in the existing 3D DRAM manufacturing process, the transistors usually adopt a structure of multi-layer stacked lateral transistors. However, in the structure of multi-layer stacked lateral transistors, because the channel areas of the lateral transistors are floating, charges are easy to accumulate in the channel areas to bring about floating body effect. The floating body effect will bring about many adverse consequences (such as kink phenomenon, BJT amplification, reduction of drain breakdown voltage, increase of GIDL current, etc.), which will seriously affect the performance of the device and even make the device fail.

### SUMMARY

The disclosure relates to the field of memories, and in particular to a three- dimensional semiconductor structure and a method for forming the same.

Some embodiments of the disclosure provide a method for forming a three- dimensional semiconductor structure, including the following operations.

A semiconductor substrate is provided.

A stack structure of sacrificial layers and semiconductor layers stacked alternately is formed on the semiconductor substrate. The stack structure includes, in a first direction, a channel region, and a source region and a drain region on either side of the channel region. The first direction is a direction parallel to a top surface of the semiconductor substrate.

The stack structure in the source region and the drain region is etched to form a plurality of parallel first trenches extending in the first direction and penetrating the stack structure in the source region and the drain region perpendicularly in the stack structure in the source region and the drain region. The plurality of semiconductor layers retained in the channel region serve as a plurality of channel body layers. The channel body layers extend in a second direction. Each of the channel body layers includes a plurality of channel areas arranged in the second direction. The second direction is a direction having an included angle with the first direction and parallel to the top surface of the semiconductor substrate.

A through via is formed in one end of the plurality of channel body layers in the second direction. The through via penetrates the end perpendicularly and exposes a surface of the semiconductor substrate.

A conductive material is filled in the through via to form a grounded conductive plug.

Some embodiments of the disclosure further provide a three-dimensional semiconductor structure.

The three-dimensional semiconductor structure includes a semiconductor substrate, a stack structure of sacrificial layers and semiconductor layers stacked alternately, a plurality of parallel first trenches, a through via and a grounded conductive plug.

The stack structure is located on the semiconductor substrate. The stack structure includes, in a first direction, a channel region, and a source region and a drain region on either side of the channel region. The first direction is a direction parallel to a top surface of the semiconductor substrate.

The plurality of parallel first trenches extend in the first direction and penetrate the stack structure in the source region and the drain region perpendicularly in the stack structure in the source region and the drain region. The plurality of semiconductor layers retained in the channel region serve as a plurality of channel body layers. The channel body layers extend in a second direction. Each of the channel body layers includes a plurality of channel areas arranged in the second direction. The second direction is a direction having an included angle with the first direction and parallel to the top surface of the semiconductor substrate.

The through via is located in one end of the plurality of channel body layers in the second direction. The through via penetrates the end perpendicularly and exposes a surface of the semiconductor substrate.

The grounded conductive plug is located in the through via.

### BRIEF DESCRIPTION OF THE DRAWINGS

FIGS. 1-49 are structural diagrams during forming a three-dimensional semiconductor structure in some embodiments of disclosure.

### DETAILED DESCRIPTION

Specific implementations of the disclosure will be described in detail below in combination with the accompany drawings. In detailing the embodiments of the disclosure, for the sake of illustration, schematic diagrams will not be partially enlarged in accordance with the normal scale. Also, the schematic diagrams are only exemplary, and should not limit the protection scope of the disclosure here. In addition, in practical manufacturing, the three-dimensional space dimensions of length, width and depth should be included.

Some embodiments of the disclosure provide a method for forming a three- dimensional semiconductor structure, which is described in detail below in combination with the accompany drawings.

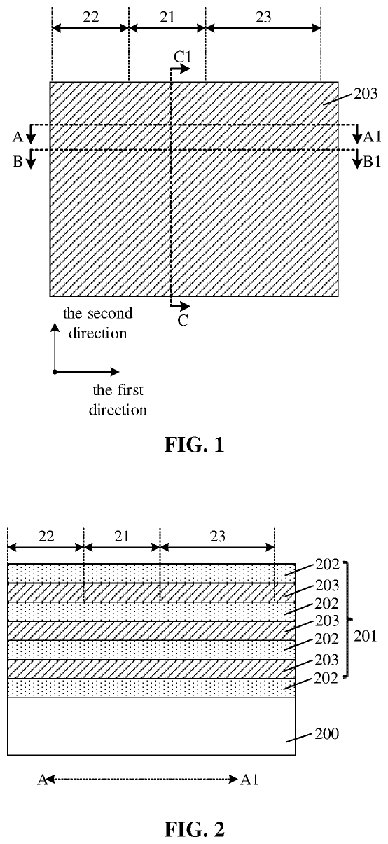

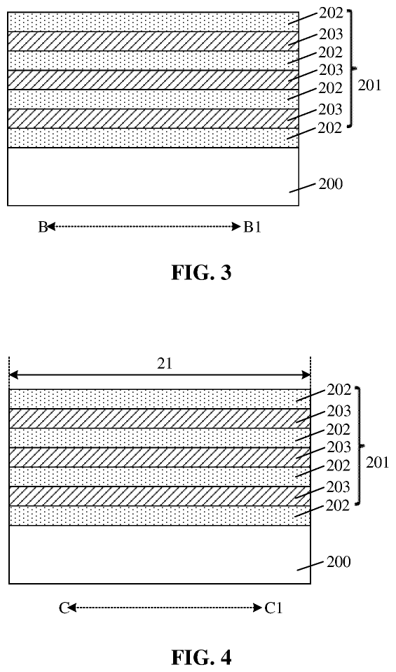

Referring to FIGS. 1-4, FIG. 2 is a cross-sectional structural diagram along a direction of a cutting line AA1 of FIG. 1, FIG. 3 is a cross-sectional structural diagram along a direction of a cutting line BB1 of FIG. 1, and FIG. 4 is a cross-sectional structural diagram along a direction of a cutting line CC1 of FIG. 1. It is to be noted that, for better illustration, a sacrificial layer (or a hard mask layer) as a top layer is not shown, and a semiconductor layer 203 at a bottom of the top layer (or the hard mask layer) is shown directly in FIG. 1. A semiconductor substrate 200 is provided. A stack structure 201 of sacrificial layers 202 and semiconductor layers 203 stacked alternately is formed on the semiconductor substrate 200. The stack structure 201 includes, in a first direction, a channel region 21, and a source region 23 and a drain region 22 on either side of the channel region 21. The first direction is a direction parallel to a top surface of the semiconductor substrate 200.

A material of the semiconductor substrate 200 may be monocrystalline silicon (Si), monocrystalline germanium (Ge), or silicon germanium (GeSi), silicon carbide (SiC), or may also be silicon on insulator (SOI) or germanium on insulator (GOI), or may also be other materials, such as Group III-V compounds, for example gallium arsenide. In the embodiment, the material of the semiconductor substrate 200 is monocrystalline silicon (Si).

The stack structure 201 includes sacrificial layers 202 and semiconductor layers 203 stacked alternately. The sacrificial layers 202 and the semiconductor layers 203 stacked alternately means that after a sacrificial layer 202 is formed, a semiconductor layer 203 is formed on a surface of the sacrificial layer 202, and then operations of forming a sacrificial layer 202 and forming a semiconductor layer 203 on the sacrificial layer 202 are sequentially repeated. The number of layers of the sacrificial layers 202 and the semiconductor layers 203 may be determined according to actual needs. In the embodiment, four sacrificial layers 202 and three semiconductor layers 203 are described as an example. A bottom layer and a top layer of the stack structure 201 are both a sacrificial layer 202. In another embodiment, the top layer of the stack structure 201 may be a semiconductor layer 203. A hard mask layer is formed on a surface of the top semiconductor layer 203. In other embodiments, the number of layers of the sacrificial layers 202 and the semiconductor layers 203 may be other numbers.

The semiconductor layers 203 are subsequently used to form channel areas, source areas and drain areas of lateral transistors. The sacrificial layers 202 will be removed as a sacrificial material in a subsequent process, or part of the sacrificial layer 202 may subsequently be directly used as part of an insulating layer. A material of the sacrificial layers 202 is different from a material of the semiconductor layers 203, so that the sacrificial layers 202 have a high etch selectivity ratio (an etch selectivity ratio greater than 2:1) with respect to the semiconductor layers 203 (or a linear semiconductor pattern) when the sacrificial layers 202 are subsequently removed, so as to make the semiconductor layers 203 (or a linear semiconductor pattern) not etched or be etched in a small amount while the sacrificial layers 202 are removed.

In some embodiments, the material of the semiconductor layers 203 is silicon or germanium silicon, and the material of the sacrificial layers 202 is one of silicon oxide, silicon nitride, silicon oxynitride, silicon carbonnitride, amorphous silicon, amorphous carbon, polysilicon, and germanium silicon. In the embodiment, the material of the semiconductor layers 203 is silicon, and the material of the sacrificial layers 202 is germanium silicon.

In some embodiments, the semiconductor layers 203 are doped semiconductor layers 203, that is, the semiconductor layers 203 are pre-doped with impurity ions. The impurity ions may be N-type impurity ions or P-type impurity ions. In some embodiments, the P-type impurity ions are one or more of boron, gallium and indium. The N-type impurity ions include one or more of phosphorus, arsenic and antimony. In the embodiment, the impurity ions pre-doped in the semiconductor layers 203 are P-type impurity ions. In other embodiments, the semiconductor layers 203 may also be undoped semiconductor layers 203.

The sacrificial layers 202 and the semiconductor layers 203 are respectively formed by a deposition process. The deposition process includes an epitaxial process.

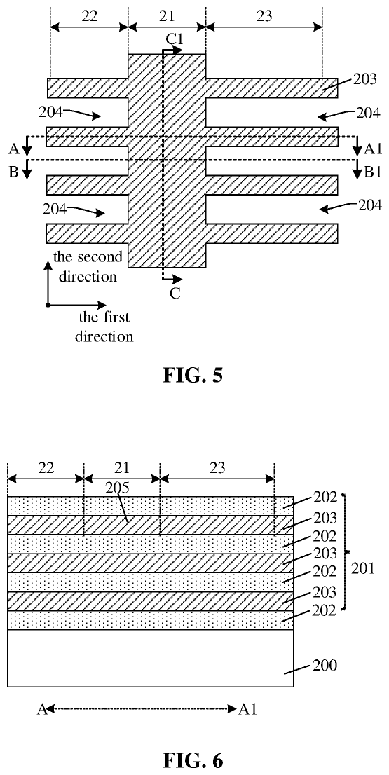

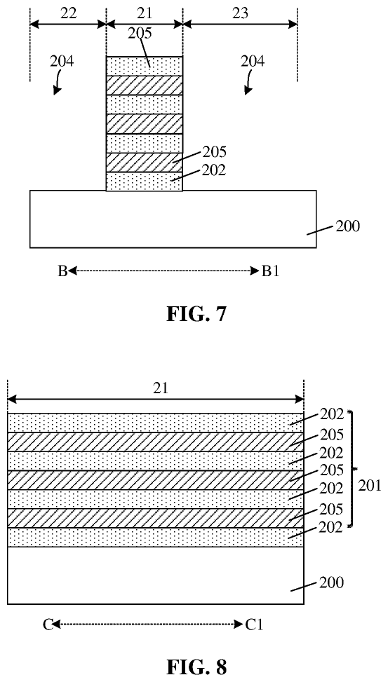

Referring to FIGS. 5-8, FIG. 6 is a cross-sectional structural diagram in a direction of a cutting line AA1 of FIG. 5, FIG. 7 is a cross-sectional structural diagram in a direction of a cutting line BB1 of FIG. 5, and FIG. 8 is a cross-sectional structural diagram in a direction of a cutting line CC1 of FIG. 5. The stack structure 201 in the source region 23 and the drain region 22 is etched to form a plurality of parallel first trenches 204 extending in the first direction and penetrating the stack structure 201 in the source region 23 and the drain region 22 perpendicularly in the stack structure 201 in the source region 23 and the drain region 22. The plurality of semiconductor layers retained in the channel region 21 serve as a plurality of channel body layers 205. The channel body layers 205 extend in a second direction. Each of the channel body layers 205 includes a plurality of channel areas arranged in the second direction.

The plurality of channel areas are correspondingly used as the channel areas of a plurality of lateral transistors. The source areas of the lateral transistors are subsequently formed in the semiconductor layers 203 retained between adjacent first trenches 204 in the source region 23. The drain areas of the lateral transistors are subsequently formed in the semiconductor layers 203 retained between adjacent first trenches 204 in the drain region 22.

The second direction is a direction having an included angle with the first direction and parallel to the top surface of the semiconductor substrate 200. In the embodiment, the first direction and the second direction are perpendicular to each other, that is, the included angle between the first direction and the second direction is 90°.

The plurality of first trenches 204 are respectively formed in the source region 23 and drain region 22 of the stack structure 201. Each of the first trenches 204 in the source region 23 is located on an extension line of a corresponding one of the first trenches 204 in the drain region 22. During etching to form the first trenches 204, the semiconductor layers 203 and the sacrificial layers 202 in the channel region 21 of the stack structure 201 are not etched, so that the remaining semiconductor layer 203 in the channel region 21 of the stack structure 201 are still continuous in the second direction. The plurality of semiconductor layers 203 retained in the channel region 21 serve as the plurality of channel body layers 205. Each of the channel body layers 205 includes a plurality of channel areas arranged in the second direction.

The second direction is a direction having an included angle with the first direction and parallel to the top surface of the semiconductor substrate 200.

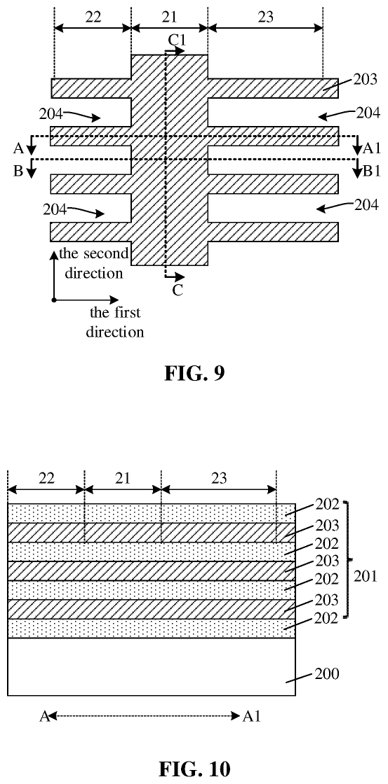

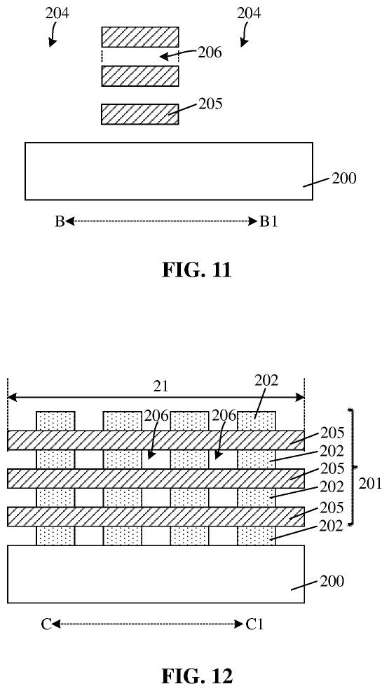

In some embodiments, referring to FIGS. 9-12, FIG. 10 is a cross-sectional structural diagram in a direction of a cutting line AA1 of FIG. 9, FIG. 11 is a cross-sectional structural diagram in a direction of a cutting line BB1 of FIG. 9, and FIG. 12 is a cross-sectional structural diagram in a direction of a cutting line CC1 of FIG. 9. The method further includes the following operations. Parts of each of the sacrificial layers 202 between the channel body layers 205 are etched and removed to form a plurality of first cavities 206. Each of the first cavities 206 is located in an extension direction of a corresponding one of the first trenches 204 and is communicated with the first trench 204.

Parts of each of the sacrificial layers between the channel body layers 205 are removed by an isotropic wet or dry etching process.

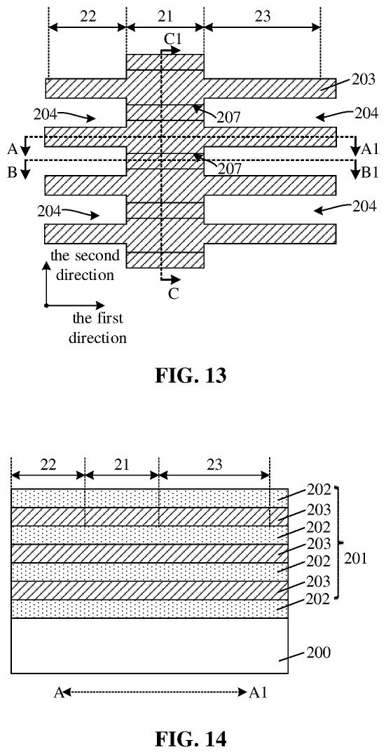

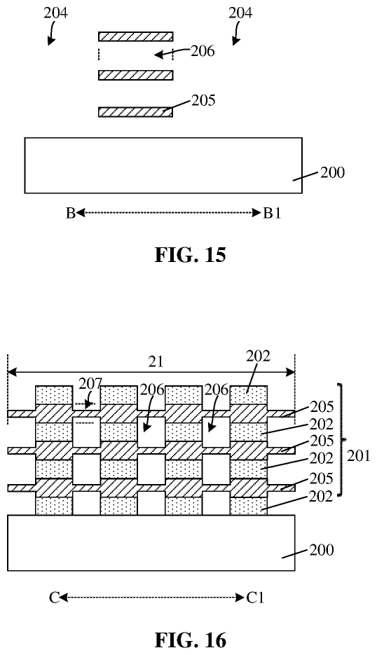

Referring to FIGS. 13-16, FIG. 14 is a cross-sectional structural diagram ing a direction of a cutting line AA1 of FIG. 13, FIG. 15 is a cross-sectional structural diagram in a direction of a cutting line BB1 of FIG. 13, and FIG. 16 is a cross-sectional structural diagram in a direction of a cutting line CC1 of FIG. 13. Parts of each of the channel body layers 205 are etched along the plurality of first cavities 206 to form a plurality of annular first openings 207 in the channel body layers 205. The channel body layers 205 retained between adjacent annular first openings 207 in the second direction serve as the channel areas.

Parts of each of the channel body layers 205 are etched by an isotropic wet or dry etching process.

The first openings 207 are subsequently filled with an isolation material to form isolation structures, which are used for electrical isolation between adjacent channel areas.

A depth of each of the annular first openings 207 is 30%-45% of a thickness of each of the channel body layers (before being etched), and a width of the annular first opening (207) in the second direction is 80%-95% of a width of the channel area in the second direction, so that the isolation structures formed subsequently in the annular first openings 207 have better isolation performance, and also adjacent channel areas can still be connected well by the remaining channel body layer 205.

In the embodiment, P-type impurity ions are doped in the formed channel areas. In other embodiments, the channel areas all may be doped with N-type impurity ions.

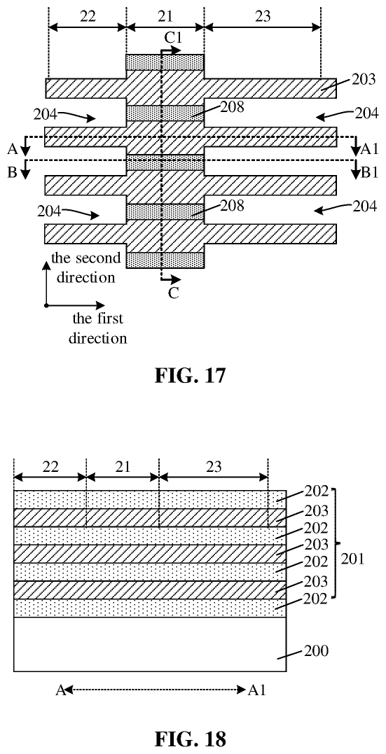

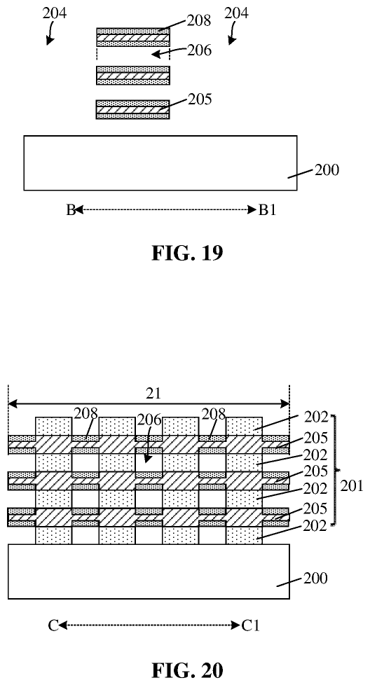

Referring to FIGS. 17-20, FIG. 18 is a cross-sectional structural diagram in a direction of a cutting line AA1 of FIG. 17, FIG. 19 is a cross-sectional structural diagram in a direction of a cutting line BB1 of FIG. 17, and FIG. 20 is a cross-sectional structural diagram in a direction of a cutting line CC1 of FIG. 17. An isolation material is filled in the plurality of first openings to form a plurality of isolation structures 208.

In some embodiments, a process for forming the isolation structures 208 includes atomic layer deposition.

The formed isolation structures 208 are used for electrical isolation between adjacent channel areas. Surfaces of the formed isolation structures 208 are flush with surfaces of the channel areas or higher than the surfaces of the channel areas.

A material of the isolation structures 208 is different from the material of the sacrificial layers 202. The material of the isolation structures 208 may be of silicon oxide, silicon nitride, silicon oxynitride, silicon oxycarbide, or silicon carbonitride. In the embodiment, the material of the isolation structures 208 is silicon oxide.

In the embodiment, the channel areas are pre-doped with P-type impurity ions, and the channel areas pre-doped with P-type impurity ions are used as the channel areas of the lateral transistors. In other embodiments, the channel areas may also be doped with impurity ions before forming the gate dielectric layers, and the channel areas of the lateral transistors are formed in the doped channel areas.

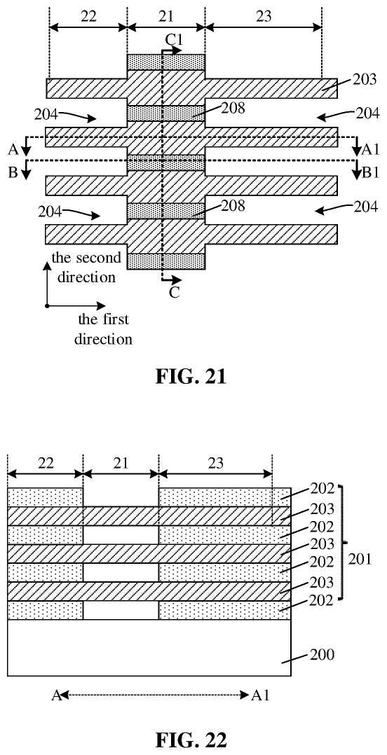

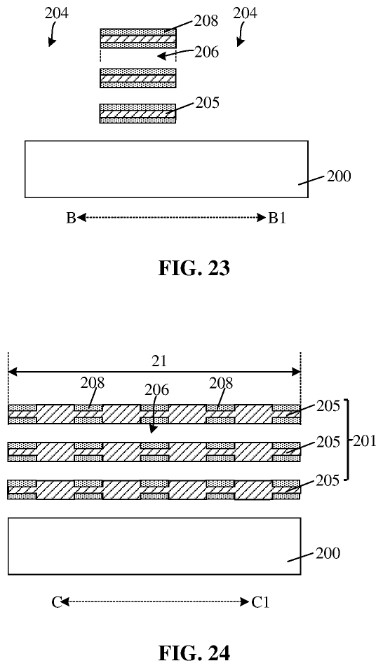

Referring to FIGS. 21-24, FIG. 22 is a cross-sectional structural diagram in a direction of a cutting line AA1 of FIG. 21, FIG. 23 is a cross-sectional structural diagram in a direction of a cutting line BB1 of FIG. 21, and FIG. 24 is a cross-sectional structural diagram in a direction of a cutting line CC1 of FIG. 21. The sacrificial layers 202 remaining in the stack structure 201 in the channel region 21 are removed, so that the channel body layers 205 are suspended.

The sacrificial layers 202 remaining in the stack structure 201 in the channel region 21 are removed by an isotropic wet or dry etching process.

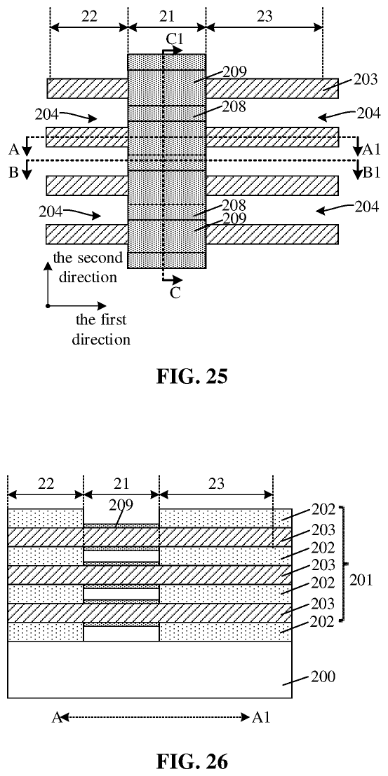

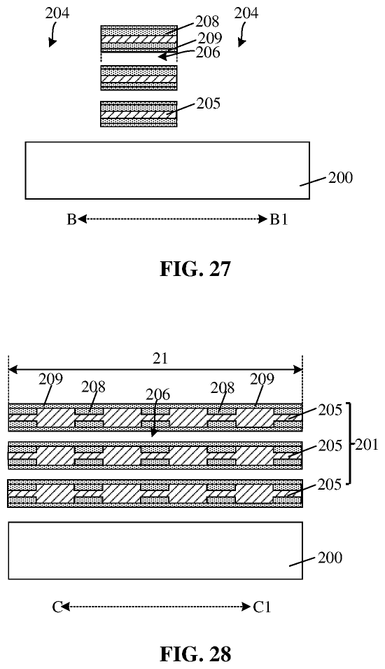

Referring to FIGS. 25-28, FIG. 26 is a cross-sectional structural diagram in a direction of a cutting line AA1 of FIG. 25, FIG. 27 is a cross-sectional structural diagram in a direction of a cutting line BB1 of FIG. 25, and FIG. 28 is a cross-sectional structural diagram in a direction of a cutting line CC1 of FIG. 25. Gate dielectric layers 209 are formed on surfaces of the plurality of isolation structures 208 and the plurality of channel areas.

Each of the gate dielectric layers 209 is part of a corresponding one of the word line structures. The gate dielectric layers 209 are used for isolation between the metal word lines formed subsequently and the channel areas. In an embodiment, a material of the gate dielectric layers 209 may be silicon oxide or a high K (K greater than 2.5) dielectric material.

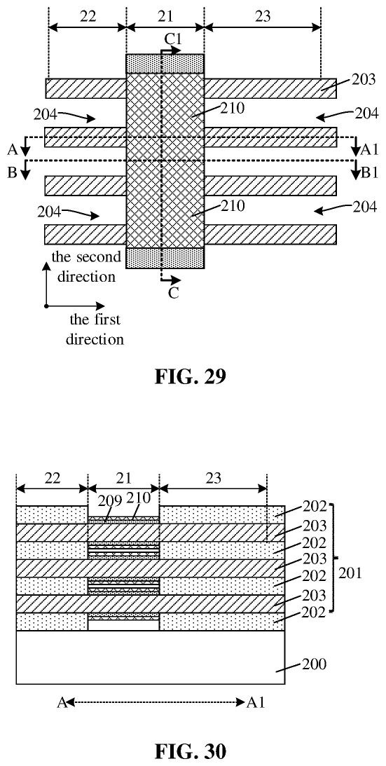

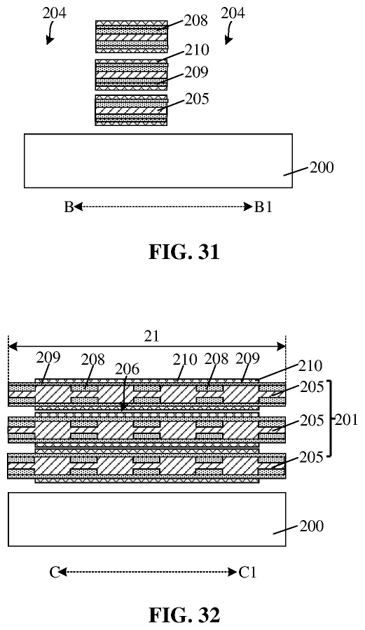

Referring to FIGS. 29-32, FIG. 30 is a cross-sectional structural diagram in a direction of a cutting line AA1 of FIG. 29, FIG. 31 is a cross-sectional structural diagram in a direction of a cutting line BB1 of FIG. 29, and FIG. 32 is a cross-sectional structural diagram in a direction of a cutting line CC1 of FIG. 29. The metal word lines 210 are formed on surfaces of the gate dielectric layers 209.

Each of the metal word lines 210 is part of a corresponding one of the word line structures. The word line structure includes a gate dielectric layer 209 and a metal word line 210 located on the surface of the gate dielectric layer 209. In an embodiment, a material of the metal word lines 210 may be one or more of Al, Cu, Ag, Au, Pt, Ni, Ti, TiN, TaN, Ta, TaC, TaSiN, W, WN, WSi.

The metal word lines 210 are horizontal word lines (horizontal word lines are arranged horizontally and parallel to the surface of the semiconductor substrate 200). The plurality of channel areas in each layer correspond to one metal word line 210, and the metal word lines 210 in adjacent layers are discrete or separated.

In some embodiments, the metal word line has a structure of double-layer gates. The double-layer gates in the metal word line are respectively located on an upper surface and a lower surface of a plurality of isolation structures and a plurality of channel areas in a certain layer.

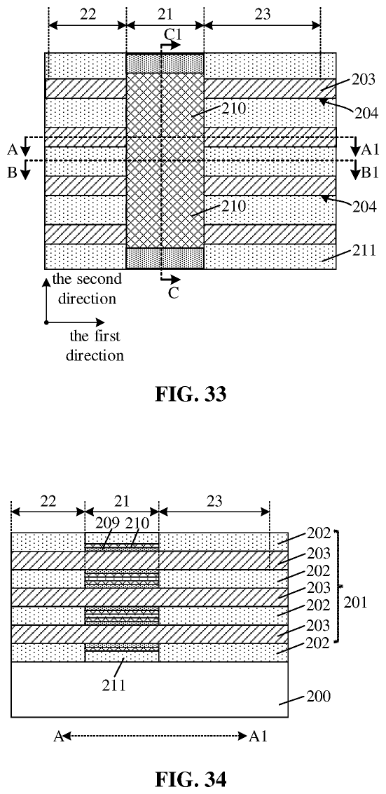

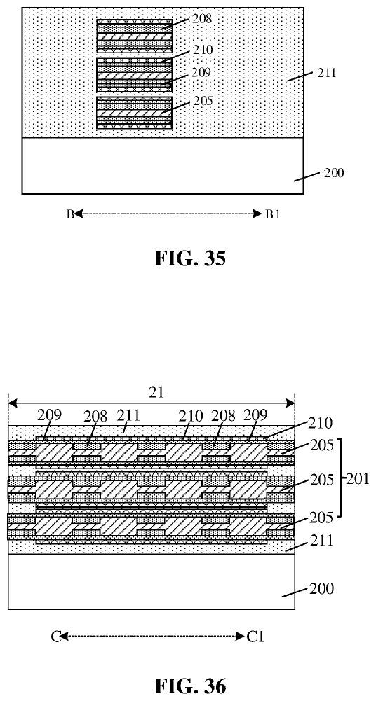

Referring to FIGS. 33-36, FIG. 34 is a cross-sectional structural diagram in a direction of a cutting line AA1 of FIG. 33, FIG. 35 is a cross-sectional structural diagram in a direction of a cutting line BB1 of FIG. 33, and FIG. 36 is a cross-sectional structural diagram in a direction of a cutting line CC1 of FIG. 33. An insulating layer 211 is filled between the word line structures.

A material of the insulating layer 211 may be one or more of silicon oxide, silicon nitride, silicon oxynitride, silicon oxycarbide, silicon carbonitride, FSG (fluorine-doped silicon dioxide), BSG (boron-doped silicon dioxide), PSG (phosphorus-doped silicon dioxide) or BPSG (boron-phosphorus-doped silicon dioxide), and a low dielectric constant (K less than 2.5) material.

A process for forming the insulating layer 211 includes a deposition process.

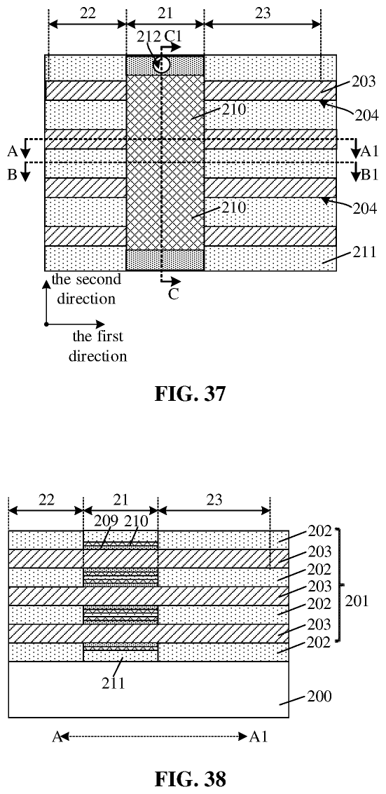

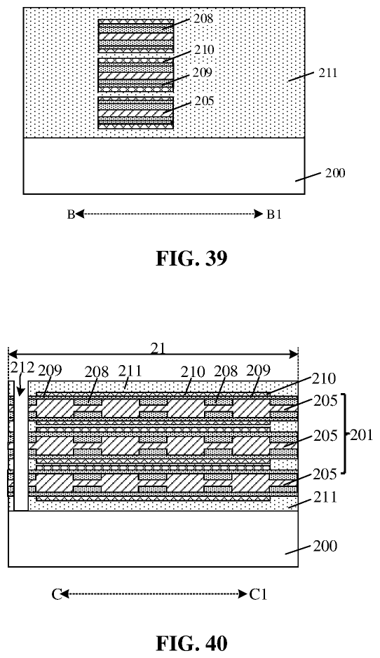

Referring to FIGS. 37-40, FIG. 38 is a cross-sectional structural diagram in a direction of a cutting line AA1 of FIG. 37, FIG. 39 is a cross-sectional structural diagram in a direction of a cutting line BB1 of FIG. 37, and FIG. 40 is a cross-sectional structural diagram in a direction of a cutting line CC1 of FIG. 37. A through via 212 is formed in one end of the plurality of channel body layers 205 in the second direction. The through via 212 penetrates the end and exposes a surface of the semiconductor substrate 200.

Each of the channel body layers 205 has two opposite ends at either end of the channel body layer 205 in the second direction. A grounded conductive plug to ground the plurality of the channel body layers 205 is intended to formed in one end, and Stepped lead wires to lead out the metal word lines 210 in each layer is intended to formed at a surface of another end.

A conductive material is filled subsequently in the through via 212 to form a grounded conductive plug.

A process for forming the through via 212 is an anisotropic dry etching process, including an anisotropic plasma etching process.

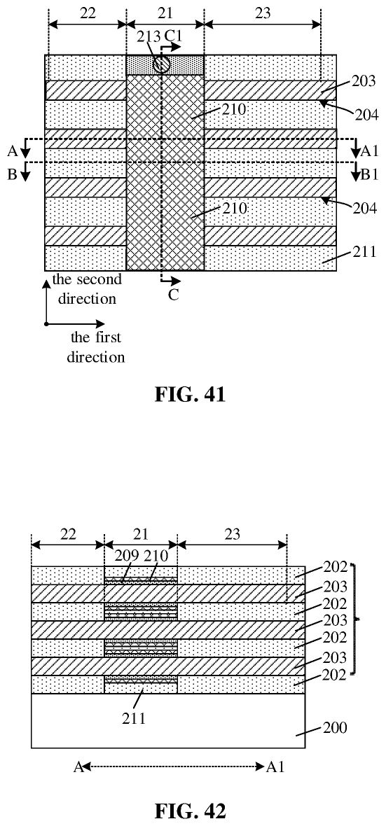

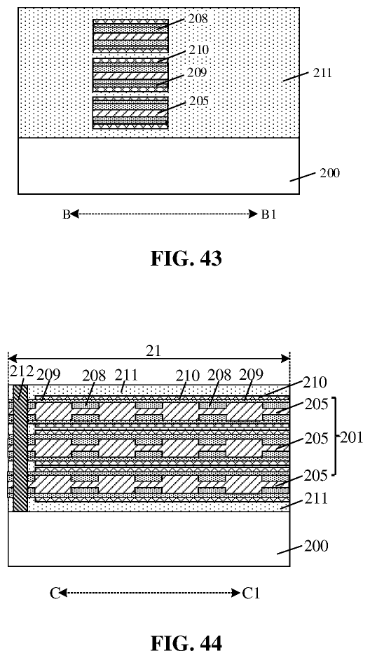

Referring to FIGS. 41-44, FIG. 42 is a cross-sectional structural diagram in a direction of a cutting line AA1 of FIG. 41, FIG. 43 is a cross-sectional structural diagram in a direction of a cutting line BB1 of FIG. 41, and FIG. 44 is a cross-sectional structural diagram in a direction of a cutting line CC1 of FIG. 41. A conductive material is filled in the through via to form a grounded conductive plug 213.

A material of the grounded conductive plug 213 is a metal or doped polysilicon. The metal may be one or more of Al, Cu, Ag, Au, Pt, Ni, Ti, TiN, TaN, Ta, TaC, TaSiN, W, WN and WSi.

A bottom end of the grounded conductive plug 213 is connected with the grounded end of the semiconductor substrate 200. By forming the connection of the grounded conductive plug 213 with the plurality of channel body layers 205, the plurality of channel areas can be grounded, thereby releasing accumulated charges in the plurality of channel areas to the grounded end of the semiconductor substrate through the channel body layers 205 and the grounded conductive plug 213. Therefore, the accumulation of charges is prevented, and further generation of floating body effect is prevented, and thus performance of the device is improved. Moreover, the grounded conductive plug 213 is formed in one end of the plurality of channel body layers 205, and does not occupy too much area, which can ensure the integration of the formed 3D DRAM device.

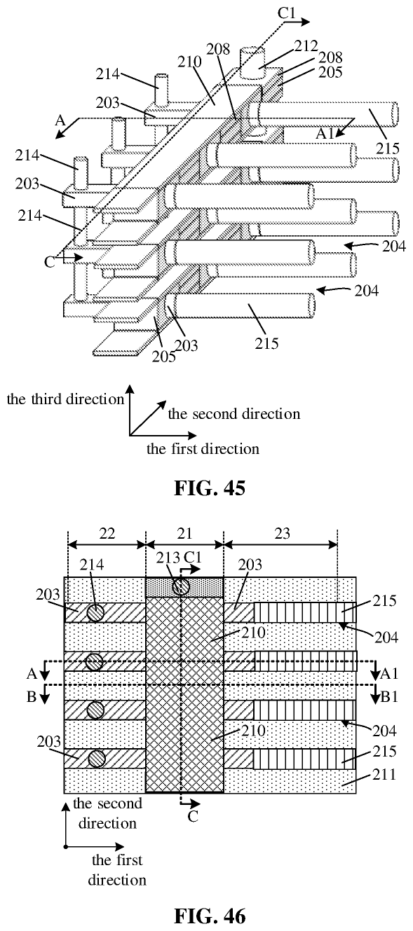

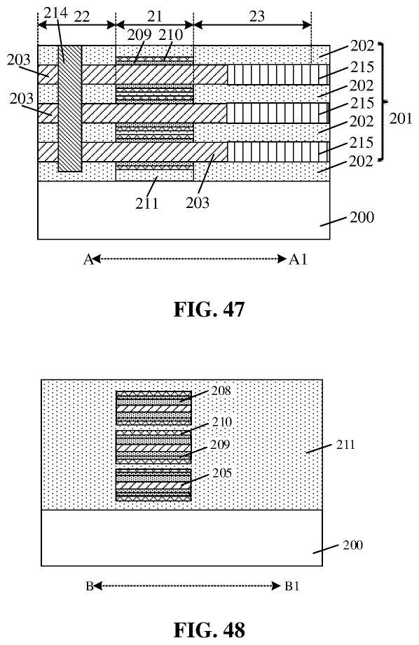

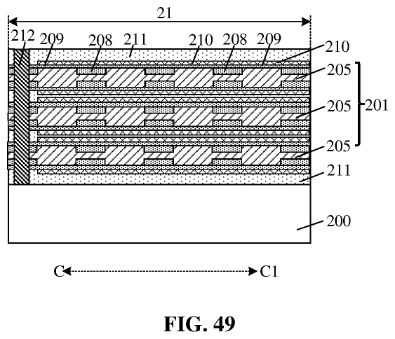

In some embodiments, referring to FIGS. 45-49 (it is to be noted that, for convenience of illustration, some structures are not shown in FIG. 45, such as the insulating layer 211), FIG. 46 is a top view of FIG. 45, FIG. 47 is a cross-sectional structural diagram in a direction of a cutting line AA1 of FIG. 45 or FIG. 46, FIG. 48 is a cross-sectional structural diagram in a direction of a cutting line BB1 of FIG. 45 or FIG. 46, and FIG. 49 is a cross-sectional structural diagram in a direction of a cutting line CC1 of FIG. 45 or FIG. 46. The plurality of semiconductor layers extending in the first direction remained between adjacent first trenches in the drain region 22 are doped to form drain areas. The plurality of semiconductor layers extending in the first direction remained between adjacent first trenches in the source region 23 are doped to form source areas. Each of the source areas is located in an extending direction of a corresponding one of the drain areas, and both the source area and the corresponding drain area are connected with a corresponding one of the channel areas. Second through vias each penetrating a plurality of drain areas in a vertical direction are formed. The vertical direction is a direction perpendicular to the top surface of the semiconductor substrate. Bit lines 214 are formed in the second through vias. The sacrificial layers remaining in the source region are removed. Capacitors 215 connected with the source areas are formed.

In some embodiments, a doping type of the drain areas is the same as a doping type of the source areas and is opposite to a doping type of the channel areas.

A material of the bit line 214 is a metal. The metal may be one or more of Al, Cu, Ag, Au, Pt, Ni, Ti, TiN, TaN, Ta, TaC, TaSiN, W, WN and WSi.

Some embodiments of the disclosure further provide a three-dimensional semiconductor structure.

The three-dimensional semiconductor structure includes a semiconductor substrate 200, a stack structure 201 of insulating layers (202/211) and semiconductor layers 203 stacked alternately, a plurality of parallel first trenches 204, a through via and a grounded conductive plug 213.

The stack structure 201 is located on the semiconductor substrate. The stack structure 201 includes, in a first direction, a channel region 21, and a source region 23 and a drain region 22 on either side of the channel region 21. The first direction is a direction parallel to a top surface of the semiconductor substrate 200.

The plurality of parallel first trenches 204 extend in the first direction and penetrate the stack structure 201 in the source region 23 and the drain region 22 perpendicularly in the stack structure 201 of the source region 23 and the drain region 22. The plurality of semiconductor layers retained in the channel region 21 serve as a plurality of channel body layers 205. The channel body layers 205 extend in a second direction. Each of the channel body layers includes a plurality of channel areas arranged in the second direction. The second direction is a direction having an included angle with the first direction and parallel to the top surface of the semiconductor substrate 200.

The through via is located in one end of the plurality of channel body layers 205 in the second direction. The through via penetrates the end perpendicularly and exposes a surface of the semiconductor substrate 200.

The grounded conductive plug 213 is located in the through via.

In some embodiments, the three-dimensional semiconductor structure further includes a plurality of annular first openings located in the channel body layers 205, a plurality of isolation structures 208 filling the plurality of first openings, and word line structures (209/210) extending in the second direction on surfaces of the plurality of isolation structures 208 and the plurality of channel areas. The first openings communicate with the first trenches. The channel body layers retained between adjacent annular first openings in the second direction serve as the channel areas.

In some embodiments, the three-dimensional semiconductor structure also includes drain areas in the plurality of semiconductor layers extending in the first direction remained between adjacent first trenches in the drain region 22.

In some embodiments, the three-dimensional semiconductor structure further includes source areas in the plurality of semiconductor layers extending in the first direction remained between adjacent first trenches in the source region. Each of the source areas is located in an extending direction of a corresponding one of the drain areas, and both the source area and the corresponding drain area are connected with a corresponding one of the channel areas.

In some embodiments, a doping type of the drain areas is the same as a doping type of the source areas and is opposite to a doping type of the channel areas.

In some embodiments, the three-dimensional semiconductor structure further includes second through vias each penetrating a plurality of drain areas in a vertical direction, and bit lines 214 in the second through vias.

In some embodiments, the three-dimensional semiconductor structure further includes capacitors 215 connected with the source areas.

In some embodiments, the semiconductor substrate 200 has a grounded end, and the grounded conductive plug 213 is connected with the grounded end.

In some embodiments, a material of the grounded conductive plug is a doped semiconductor material or a metal.

In some embodiments, a depth of each of the annular first openings is 30%-45% of a thickness of each of the channel body layers, and a width of the annular first opening in the second direction is 80%-95% of a width of the channel area in the second direction.

In some embodiments, the word line structure includes a gate dielectric layer 209 and a metal word line 210 located on a surface of the gate dielectric layer 209.

In some embodiments, the metal word line has a structure of double-layer gates. The double-layer gates in the metal word line are respectively located on an upper surface and a lower surface of a plurality of isolation structures and a plurality of channel areas of a certain layer.

It is to be noted that a definition or description of a same or similar part in some embodiments of the foregoing semiconductor structure as in some embodiments of the forgoing method for forming a semiconductor structure will not be repeated herein. The definition or description of the corresponding part in some embodiments of the foregoing method for forming 3D DARM is referred to for details.

Although the disclosure has been disclosed as above with preferred embodiments, the embodiments are not used to limit the protection scope of the disclosure. Any skilled in the art can make possible changes and modifications to the technical solutions of the disclosure by using the methods and technical contents disclosed above without departing from the spirit and scope of the disclosure. Therefore, any simple modification, equivalent change or variant made to the above embodiments according to the technical essence of the disclosure without departing from the contents of the technical solutions of the disclosure belongs to the protection scope of the technical solutions of the disclosure.

1. A method for forming a three-dimensional semiconductor structure, comprising:
providing a semiconductor substrate;
forming a stack structure of sacrificial layers and semiconductor layers stacked alternately on the semiconductor substrate, wherein the stack structure comprises, in a first direction, a channel region, and a source region and a drain region on either side of the channel region, wherein the first direction is a direction parallel to a top surface of the semiconductor substrate;
etching the stack structure in the source region and the drain region to form a plurality of parallel first trenches extending in the first direction and penetrating the stack structure in the source region and the drain region perpendicularly in the stack structure in the source region and the drain region, wherein the semiconductor layers retained in the channel region serve as a plurality of channel body layers, wherein the channel body layers extend in a second direction, each of the channel body layers comprises a plurality of channel areas arranged in the second direction, and the second direction is a direction having an included angle with the first direction and parallel to the top surface of the semiconductor substrate;
forming a through via in one end of the plurality of channel body layers in the second direction, wherein the through via penetrates the end and exposes a surface of the semiconductor substrate; and
filling a conductive material in the through via to form an grounded conductive plug.

2. The method for forming a three-dimensional semiconductor structure of claim 1, further comprising: etching and removing parts of each of the sacrificial layers between the channel body layers to form a plurality of first cavities, wherein each of the first cavities is located in an extension direction of a corresponding one of the plurality of parallel first trenches and communicated with the corresponding one of the plurality of parallel first trenches;
etching parts of each of the channel body layers along the plurality of first cavities to form a plurality of annular first openings in the channel body layers, wherein the channel body layers retained between adjacent annular first openings in the second direction serve as the channel areas;
filling an isolation material in the plurality of annular first openings to form a plurality of isolation structures;
removing the sacrificial layers remaining in the stack structure in the channel region; and
forming word line structures extending in the second direction on surfaces of the plurality of isolation structures and the plurality of channel areas.

3. The method for forming a three-dimensional semiconductor structure of claim 2, further comprising: doping the semiconductor layers extending in the first direction retained between adjacent first trenches in the drain region to form drain areas, and doping the semiconductor layers extending in the first direction retained between adjacent first trenches in the source region to form source areas, wherein each of the source areas is located in an extending direction of a corresponding one of the drain areas, and both each of the source areas and the corresponding one of the drain areas are connected with a corresponding one of the channel areas.

4. The method for forming a three-dimensional semiconductor structure of claim 3, wherein a doping type of the drain areas is a same as a doping type of the source areas and is opposite to a doping type of the channel areas.

5. The method for forming a three-dimensional semiconductor structure of claim 4, wherein the semiconductor layers are pre-doped with P-type impurity ions, and impurity ions doped in the channel areas are P-type impurity ions.

6. The method for forming a three-dimensional semiconductor structure of claim 3, further comprising: forming second through vias each penetrating a plurality of drain areas in a vertical direction, and forming bit lines in the second through vias.

7. The method for forming a three-dimensional semiconductor structure of claim 1, wherein the semiconductor substrate has a grounded end, and the grounded conductive plug is connected with the grounded end.

8. The method of forming a three-dimensional semiconductor structure of claim 1, wherein a material of the grounded conductive plug is a doped semiconductor material or a metal.

9. The method for forming a three-dimensional semiconductor structure of claim 2, wherein a depth of each of the plurality of annular first openings is 30%-45% of a thickness of each of the channel body layers, and a width of each of the plurality of annular first openings in the second direction is 80%-95% of a width of each of the channel areas in the second direction.

10. The method of forming a three-dimensional semiconductor structure of claim 2, further comprising: filling an insulating layer between the word line structures.

11. A three-dimensional semiconductor structure, comprising:
a semiconductor substrate;
a stack structure of insulating layers and semiconductor layers stacked alternately on the semiconductor substrate, wherein the stack structure comprises, in a first direction, a channel region, and a source region, and a drain region on either side of the channel region, wherein the first direction is a direction parallel to a top surface of the semiconductor substrate;
a plurality of parallel first trenches extending in the first direction and penetrating the stack structure in the source region and the drain region perpendicularly in the stack structure in the source region and the drain region, wherein the semiconductor layers retained in the channel region serve as a plurality of channel body layers, wherein the channel body layers extend in a second direction, each of the channel body layers comprises a plurality of channel areas arranged in the second direction, and the second direction is a direction having an included angle with the first direction and parallel to the top surface of the semiconductor substrate;
a through via in one end of the plurality of channel body layers in the second direction, wherein the through via penetrates the ends perpendicularly and exposes a surface of the semiconductor substrate; and
a grounded conductive plug in the through via.

12. The three-dimensional semiconductor structure of claim 11, further comprising: a plurality of annular first openings located in the channel body layers, wherein the plurality of annular first openings are communicated with the plurality of parallel first trenches, and the channel body layers retained between adjacent annular first openings in the second direction serve as the channel areas;
a plurality of isolation structures filling the plurality of annular first openings; and
word line structures extending in the second direction on surfaces of the plurality of isolation structures and the plurality of channel areas.

13. The three-dimensional semiconductor structure of claim 12, further comprising: drain areas in the semiconductor layers extending in the first direction retained between adjacent first trenches in the drain region, and source areas in the semiconductor layers extending in the first direction retained between adjacent first trenches in the source region, wherein each of the source areas is located in an extending direction of a corresponding one of the drain areas, and both each of the source areas and the corresponding one of the drain areas are connected with a corresponding one of the channel areas.

14. The three-dimensional semiconductor structure of claim 13, wherein a doping type of the drain areas is a same as a doping type of the source areas and is opposite to a doping type of the channel areas.

15. The three-dimensional semiconductor structure of claim 13, further comprising: second through vias each penetrating a plurality of drain areas in a vertical direction, and bit lines in the second through vias.

16. The three-dimensional semiconductor structure of claim 11, wherein the semiconductor substrate has a grounded end, and the grounded conductive plug is connected with the grounded end.

17. The three-dimensional semiconductor structure of claim 11, wherein a material of the grounded conductive plug is a doped semiconductor material or a metal.

18. The three-dimensional semiconductor structure of claim 12, wherein a depth of each of the plurality of annular first openings is 30%-45% of a thickness of each of the channel body layers, and a width of each of the plurality of annular first openings in the second direction is 80%-95% of a width of each of the channel areas in the second direction.
